(19) United States
(12) Patent Application Publication
(10) Pub. No.: US 2021/0225911 A1
(43) Pub. Date: Jul. 22, 2021

(54) SOLID-STATE IMAGE SENSOR

(71) Applicant: SONY SEMICONDUCTOR SOLUTIONS CORPORATION, KANAGAWA (JP)

(72) Inventors: YUSUKE MATSUMURA, KANAGAWA (JP); TAKUYA TOYOFUKU, KANAGAWA (JP)

(21) Appl. No.: 17/250,657

(22) PCT Filed: Jun. 21, 2019
(86) PCT No.: PCT/JP2019/024715

§ 371 Date: Feb. 16, 2021

(30) Foreign Application Priority Data
Aug. 29, 2018 (JP) 2018-160090

(51) Int. Cl. H01L 27/146; H01L 27/148; H04N 5/3745

(52) U.S. Cl. CPC H01L 27/14612; H01L 27/14831; H04N 5/37457; H01L 27/14643; H01L 27/14603; H01L 27/14636

(57) ABSTRACT

A solid-state image sensor includes: a floating diffusion to which signal charges that have been accumulated in a photodiode that performs photoelectric conversion are transferred; a common-source amplifier transistor that reads the signal charges that have been transferred to the floating diffusion as an electrical signal and amplifies the electrical signal; a first wiring that connects the floating diffusion and the amplifier transistor to each other; and a second wiring disposed on an electrically-downstream side of the amplifier transistor, in which at least a part of the first wiring and at least a part of the second wiring face each other.

### TECHNICAL FIELD

The technology according to the present disclosure (the present technology) relates to, for example, a solid-state image sensor used for an imaging device.

### BACKGROUND ART

As a technology for sensitizing a solid-state image sensor, for example, there is a technology in which an amplifier transistor is connected to be source-grounded as in the technology disclosed in Patent Literature 1.

### CITATION LIST

### Patent Literature

Patent Literature 1: Japanese Patent Application Laid-open No. 2008-271280

### DISCLOSURE OF INVENTION

### Technical Problem

However, in the technology disclosed in Patent Literature 1, since the variation in the feedback capacitance for determining the conversion efficiency is increased as compared with the technology in which the amplifier transistor is connected to be drain-grounded, there is a problem that the variation in the conversion efficiency is increased.

In view of the above-mentioned problem, an object of the present technology is to provide a solid-state image sensor capable of reducing the variation in the conversion efficiency.

### Solution to Problem

A solid-state image sensor according to an embodiment of the present technology includes: a floating diffusion; a common-source amplifier transistor; a first wiring; and a second wiring.

Signal charges that have been accumulated in a photodiode that performs photoelectric conversion are transferred to the floating diffusion. The amplifier transistor reads the signal charges that have been transferred to the floating diffusion as an electrical signal and amplifies the electrical signal. The first wiring connects the floating diffusion and the amplifier transistor to each other. The second wiring is disposed on an electrically-downstream side of the amplifier transistor. Further, at least a part of the first wiring and at least a part of the second wiring face each other.

### BRIEF DESCRIPTION OF DRAWINGS

FIG. 1 is a cross-sectional view showing a configuration of a solid-state image sensor according to a first embodiment.

FIG. 2 is a cross-sectional view taken along the line II-II in FIG. 1.

FIG. 3 is a cross-sectional view showing a configuration of a solid-state image sensor according to a second embodiment.

FIG. 4 is a cross-sectional view showing a configuration of a solid-state image sensor according to a third embodiment.

FIG. 5 is a cross-sectional view taken along the line V-V in FIG. 4.

FIG. 6 is a cross-sectional view showing a configuration of a solid-state image sensor according to a fourth embodiment.

FIG. 7 is a cross-sectional view taken along the line VII-VII in FIG. 6.

FIG. 8 is a cross-sectional view taken along the line VIII-VIII in FIG. 6.

FIG. 9 is a cross-sectional view showing a modified example of the fourth embodiment.

FIG. 10 is a cross-sectional view showing a configuration of a solid-state image sensor according to the modified example of the fourth embodiment.

FIG. 11 is a cross-sectional view taken along the line XI-XI in FIG. 10.

FIG. 12 is a cross-sectional view showing a configuration of a solid-state image sensor according to a fifth embodiment.

FIG. 13 is a cross-sectional view showing a configuration of a solid-state image sensor according to a modified example of the fifth embodiment.

FIG. 14 is a cross-sectional view showing a configuration of a solid-state image sensor according to a sixth embodiment.

FIG. 15 is a cross-sectional view showing a configuration of a solid-state image sensor according to a modified example of the sixth embodiment.

FIG. 16 is a cross-sectional view showing a configuration of a solid-state image sensor according to a seventh embodiment.

FIG. 17 is a cross-sectional view taken along the line XII-XII in FIG. 16.

FIG. 18 is a cross-sectional view taken along the line XIII-XIII in FIG. 16.

FIG. 19 is a cross-sectional view showing a modified example of the seventh embodiment.

FIG. 20 is a cross-sectional view showing a configuration of a solid-state image sensor according to a modified example of the seventh embodiment.

FIG. 21 is a cross-sectional view taken along the line XXI-XXI in FIG. 20.

FIG. 22 is a cross-sectional view showing a configuration of a solid-state image sensor according to an eighth embodiment.

FIG. 23 is a cross-sectional view taken along the line XXIII-XXIII in FIG. 22.

FIG. 24 is a cross-sectional view taken along the line XXIV-XXIV in FIG. 22.

FIG. 25 is a cross-sectional view showing a modified example of the eighth embodiment.

FIG. 26 is a cross-sectional view showing a configuration of a solid-state image sensor according to the modified example of the eighth embodiment.

FIG. 27 is a cross-sectional view taken along the line XXVII-XXVII in FIG. 26.

FIG. 28 is a cross-sectional view showing a configuration of a solid-state image sensor according to a ninth embodiment.

FIG. 29 is a cross-sectional view showing an example of an imaging device as a first application example of the present technology.

FIG. 30 is a cross-sectional view showing an example of an electronic apparatus as a second application example of the present technology.

### MODE(S) FOR CARRYING OUT THE INVENTION

Hereinafter, embodiments of the present technology will be described with reference to the drawings. In the description of the drawings, the same or similar components are denoted by the same or similar reference symbols, and repetitive description thereof is omitted. Each of the drawings is schematic and includes different cases than actual ones. The embodiments shown below illustrate an apparatus and a method for embodying the technical idea of the present technology, and the technical idea of the present technology is not specified in the apparatus and the method exemplified in the embodiments described below. Various modifications can be made to the technical idea of the present technology within the technical scope described in the claims.

### First Embodiment

<Configuration of Entire Solid-State Image Sensor>

A solid-state image sensor according to a first embodiment constitutes, for example, one pixel (unit pixel) included in a solid-state imaging device used for a monitoring camera or the like, such as a CCD image sensor and a CMOS image sensor.

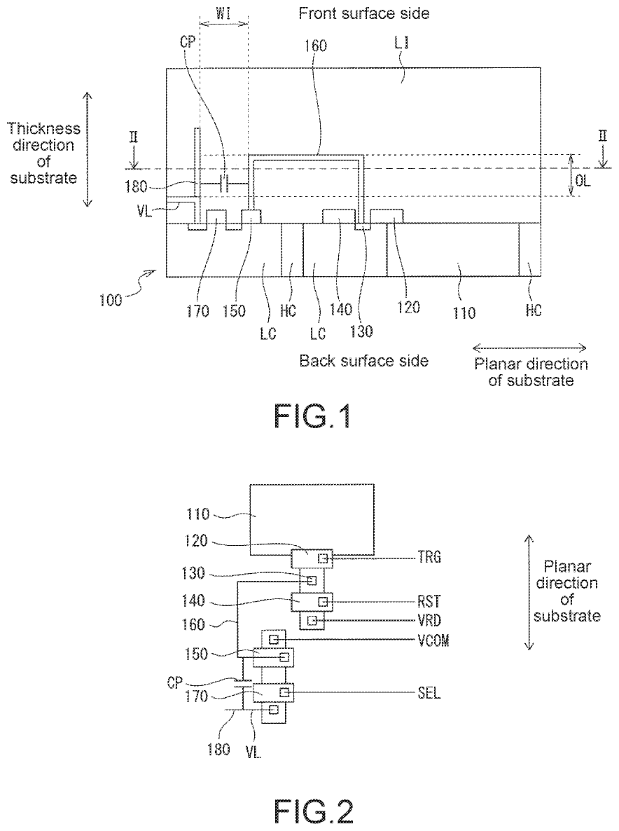

Further, in the first embodiment, a case where the solid-state image sensor constitutes a pixel of a so-called back surface irradiation solid-state imaging device will be illustrated. Therefore, in the following description, a light receiving surface (lower surface of the semiconductor substrate 100) of a semiconductor substrate 100 of the solid-state image sensor in FIG. 1 will be referred to as the “back surface”, and a surface (upper surface of the semiconductor substrate 100) opposed to the back surface of the semiconductor substrate 100 will be referred to as the “front surface” in some cases.

As shown in FIG. 1 and FIG. 2, the solid-state image sensor includes a photodiode 110, a transfer transistor 120, a floating diffusion 130, a reset transistor 140, and an amplifier transistor 150. In addition thereto, the solid-state image sensor includes a first wiring 160, a selection transistor 170, a vertical signal line VL, and a second wiring 180. Note that illustration of a high-concentration region HC and an insulating layer LI shown in FIG. 1 is omitted in FIG. 2.

The high-concentration region HC is a region in which the doping amount is larger than that in another region (low-concentration region LC) in which the solid-state image sensor is formed. The insulating layer LI includes, for example, a silicone oxide film or the like.

The photodiode 110 performs photoelectric conversion on incident light, and generates and accumulates charges corresponding to the amount of photoelectrically converted light.

One end (anode electrode) of the photodiode 110 (photoelectric conversion element) is grounded. The other end (cathode electrode) of the photodiode 110 is connected to a source electrode of the transfer transistor 120.

The transfer transistor 120 is disposed between the photodiode 110 and the floating diffusion 130. A drain electrode of the transfer transistor 120 is connected to a drain electrode of the reset transistor 140 and a gate electrode of the amplifier transistor 150.

Further, the transfer transistor 120 turns on or off the transfer of charges from the photodiode 110 to the floating diffusion 130 in accordance with a drive signal TGR supplied from the timing control unit (not shown) to the gate electrode. For example, when the drive signal TGR of an H (High) level is supplied to the gate electrode, signal charges (e.g., electrons) that have been photoelectrically converted by the photodiode 110 and accumulated in the photodiode 110 are transferred to the floating diffusion 130. Meanwhile, when the drive signal TGR of a L (Low) level is supplied to the gate electrode, the transfer of the signal charges to the floating diffusion 130 is stopped. Note that the charges that have been photoelectrically converted by the photodiode 110 while the transfer transistor 120 stops transferring the signal charges to the floating diffusion 130 are accumulated in the photodiode 110. Note that in the following description, the “High level” will be described as the “H level” and the “Low level” will be described as the “L level”. Further, in the drawings, the drive signal TGR of the H level and the drive signal TGR of the L level will be denoted by the reference symbol “TGR” without distinguishing them from each other.

The floating diffusion 130 is formed at a point (connection point) connecting a drain electrode of the transfer transistor 120, a source electrode of the reset transistor 140, and the gate electrode of the amplifier transistor 150.

Further, the floating diffusion 130 accumulates charges transferred from the photodiode 110 via the transfer transistor 120 and converts them into a voltage. That is, the signal charges accumulated in the photodiode 110 are transferred to the floating diffusion 130.

In the first embodiment, a configuration in which signal charges accumulated in one photodiode 110 are transferred to one floating diffusion 130 will be described.

The reset transistor 140 has a source electrode connected to the floating diffusion 130 and a drain electrode connected to a pixel power source (not shown).

Further, the reset transistor 140 turns on or off the discharge of charges accumulated in the floating diffusion 130 in accordance with a drive signal RST supplied from the timing control unit to the gate electrode. For example, when the drive signal RST of the H-level is supplied to the gate electrode, the reset transistor 140 flushes charges to the pixel power source before the transfer of the signal charges from the photodiode 110 to the floating diffusion 130. Thus, charges accumulated in the floating diffusion 130 are discharged (reset). The amount of charges to be discharged is an amount corresponding to a drain voltage VRD. The drain voltage VRD is a reset voltage for resetting the floating diffusion 130.

Meanwhile, the reset transistor 140 electrically floats the floating diffusion 130 when the drive signal RST of the L level is supplied to the gate electrode. Note that in the drawings, the drive signal RST of the H level and the drive signal RST of the L level are denoted by the reference symbol “RST” without distinguishing them form each other.

The amplifier transistor 150 is a common-source transistor whose gate electrode is connected to the floating diffusion 130 and whose source electrode is grounded. A control voltage VCOM is input to a source electrode of the amplifier transistor 150 from a circuit (not shown). A drain electrode of the amplifier transistor 150 is connected to a source electrode of the selection transistor 170.

Further, the amplifier transistor 150 reads the potential of the floating diffusion 130 reset by the reset transistor 140 as a reset level. Further, the amplifier transistor 150 amplifies the voltage corresponding to the signal charges accumulated in the floating diffusion 130 to which the signal charges have been transferred by the transfer transistor 120. That is, the amplifier transistor 150 reads the signal charges that have been transferred to the floating diffusion 130 as an electrical signal and amplifies the read electrical signal.

The voltage (voltage signal) amplified by the amplifier transistor 150 is output to the vertical signal line VL via the selection transistor 170.

The first wiring 160 is a wiring connecting the floating diffusion 130 and the gate electrode of the amplifier transistor 150 to each other. Further, the first wiring 160 is formed by a contact-via forming process so that the length along the thickness direction of the semiconductor substrate 100 (up-and-down direction in FIG. 1) is on the order of submicron to several microns. Note that in FIG. 1, the thickness direction of the semiconductor substrate 100 is referred to as the “thickness direction of substrate”. The same applies to the following drawings.

For example, the selection transistor 170 has a drain electrode connected to one end of the vertical signal line VL and a source electrode connected to the drain electrode of the amplifier transistor 150.

Further, the selection transistor 170 turns on/off the outputting of the voltage signal from the amplifier transistor 150 to the vertical signal line VL in accordance with a drive signal SEL supplied from the timing control unit to the gate electrode. For example, the selection transistor 170 outputs a voltage signal to the vertical signal line VL when the drive signal SEL of the H level is supplied to the gate electrode. Meanwhile, when the drive signal SEL of the L level is supplied to the gate electrode, the selection transistor 170 stops the outputting of a voltage signal. Note that in the drawings, the drive signal SEL of the H level and the drive signal SEL of the L level are denoted by the reference symbol “SEL” without distinguishing them from each other.

Thus, the selection transistor 170 becomes conductive when a selection control signal is supplied to the gate electrode, and selects a unit pixel in synchronization with vertical scanning by a vertical scanning circuit (not shown). Note that the selection transistor 170 may be configured to be connected between the source electrode of the amplifier transistor 150 and a source line.

The vertical signal line VL (vertical signal line) is a wiring for outputting an electrical signal amplified by the amplifier transistor 150. A drain electrode of the selection transistor 170 is connected to one end of the vertical signal line VL. An A/D converter (not shown) is connected to the other end of the vertical signal line VL.

The second wiring 180 is a wiring that is disposed on an electrically-downstream side of the amplifier transistor 150, and one end of which is connected in the middle of the vertical signal line VL or to a node of the vertical signal line VL. In the first embodiment, as shown in FIG. 1, a configuration in which one end of the second wiring 180 is connected in the middle of the vertical signal line VL will be described.

Further, the second wiring 180 is formed by a contact-via forming process so that the length along the thickness direction of the semiconductor substrate 100 is on the order of submicron to several microns, similarly to the first wiring 160.

Further, at least a part of the second wiring 180 faces at least a part of the first wiring 160. That is, at least a part of the first wiring 160 and at least a part of the second wiring 180 face each other.

As a result, an additional capacitance CP is formed in portions where the first wiring 160 and the second wiring 180 face each other. The magnitude of the additional capacitance CP has a value according to the distance between the first wiring 160 and the second wiring 180, the facing area of the portions where the first wiring 160 and the second wiring 180 face each other, and the like. Note that in FIG. 2, for the sake of description, the position of the additional capacitance CP is illustrated at a position different from that in the configuration of FIG. 1.

Further, in the first embodiment, a configuration in which at least the portions where the first wiring 160 and the second wiring 180 face each other extend in parallel along the thickness direction of the semiconductor substrate 100 as shown in FIG. 1 and FIG. 2 will be described as an example.

Further, the portion of the first wiring 160 facing the second wiring 180 and the portion of the second wiring 180 facing the first wiring 160 are desirably formed in the same process in order to suppress the generation of variation in alignment due to the lithography process.

Further, the second wiring 180 is formed after the vertical signal line VL is formed. Therefore, the second wiring 180 can be formed thicker than the vertical signal line VL.

Further, in the first embodiment, a configuration in which at least a part of the second wiring 180 faces at least a part of the first wiring 160 along the planar direction of the semiconductor substrate 100 (the right-and-left direction in FIG. 1, the up-and-down direction in FIG. 2) as shown in FIG. 1 and FIG. 2 will be described as an example. Note that in the drawings, the planar direction of the semiconductor substrate 100 is indicated as “planar direction of substrate”. The same applies to the following drawings.

Further, in the first embodiment, a configuration in which a facing portion length OL that is the length of each of the portions where the first wiring 160 and the second wiring 180 face each other is longer than a wiring interval WI that is the interval between the portions where the first wiring 160 and the second wiring 180 face each other will be described. Note that for the purpose of description, FIG. 1 shows a configuration in which the facing portion length OL is shorter than the wiring interval WI, but the facing portion length OL is longer than the wiring interval WI in an actual configuration.

The photodiode 110, the transfer transistor 120, the floating diffusion 130, and the reset transistor 140 are formed on the semiconductor substrate 100. Further, the amplifier transistor 150, the first wiring 160, the selection transistor 170, the vertical signal line VL, and the second wiring 180 are formed on the semiconductor substrate 100.

With the configuration of the first embodiment, since at least a part of the first wiring 160 and at least a part of the second wiring 180 face each other, the conversion efficiency can be adjusted while dispersing the main variation factor of the feedback capacitance. As a result, it is possible to provide a solid-state image sensor capable of reducing the variation in conversion efficiency.

Further, since at least the portions where the first wiring 160 and the second wiring 180 face each other extend in parallel along the thickness direction of the semiconductor substrate 100, there is no need to stretch the wiring in the lateral direction in the pixel and it is easier to combine with a smaller cell-sized pixel. Further, since the wiring does not need to be stretched to the adjacent pixel side, it is possible to suppress electrical color mixing. In addition, it is possible to minimize the addition of a wiring extending in the width direction of the semiconductor substrate 100. This makes it possible to improve the flexibility of pixel layout.

Further, since the facing portion length OL is longer than the wiring interval WI, the additional capacitance CP can be increased as compared with the case where the facing portion length OL is less than or equal to the wiring interval WI.

### Second Embodiment

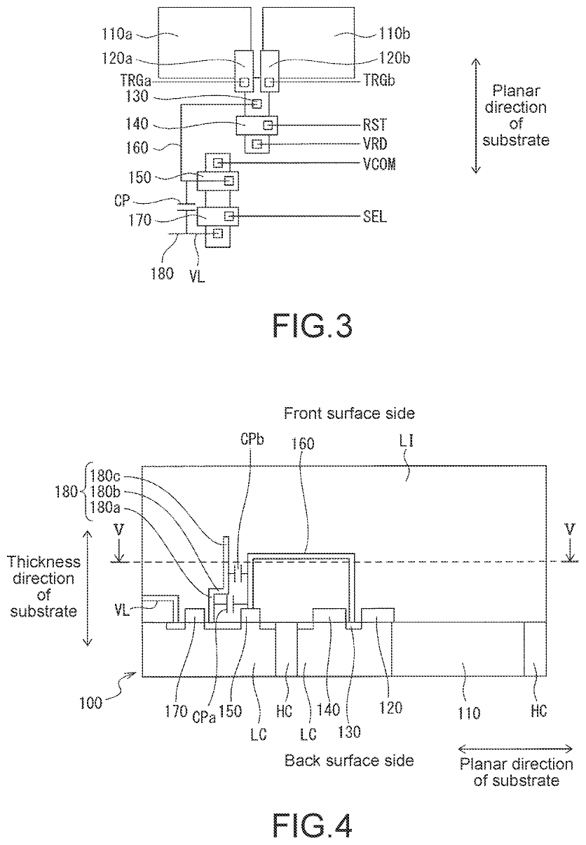

A solid-state image sensor according to a second embodiment also has a cross-sectional structure shown in FIG. 1, which is common to the structure of the solid-state image sensor according to the first embodiment. However, the solid-state image sensor according to the second embodiment is different from the first embodiment in that it includes two photodiodes 110a and 110b as shown in FIG. 3. In the following description, description of the same portions as those in the first embodiment will be omitted.

The photodiode 110a and the photodiode 110b both perform photoelectric conversion on incident light and generate and accumulate charges corresponding to the amount of photoelectrically converted light.

One end of the photodiode 110a is grounded, and the other end of the photodiode 110a is connected to a source electrode of the transfer transistor 120a.

One end of the photodiode 110b is grounded, and the other end of the photodiode 110b is connected to a source electrode of the transfer transistor 120b.

The transfer transistor 120a is disposed between the photodiode 110a and the floating diffusion 130. Further, the transfer transistor 120a turns on or off the transfer of charges from the photodiode 110a to the floating diffusion 130 in accordance with a drive signal TGRa.

The transfer transistor 120b is disposed between the photodiode 110b and the floating diffusion 130. Further, the transfer transistor 120b turns on or off the transfer of charges from the photodiode 110b to the floating diffusion 130 in accordance with a drive signal TGRb.

As described above, in the second embodiment, the signal charges accumulated in each of the plurality of the photodiodes 110 (the photodiodes 110a and 110b) are individually transferred to one floating diffusion 130.

That is, in the second embodiment, the plurality of photodiodes 110 (the photodiodes 110a and 110b) share one floating diffusion 130.

With the configuration of the second embodiment, it is possible to improve the flexibility of pixel layout without changing the size of solid-state image sensor by increasing only the number of the photodiodes 110.

### Third Embodiment

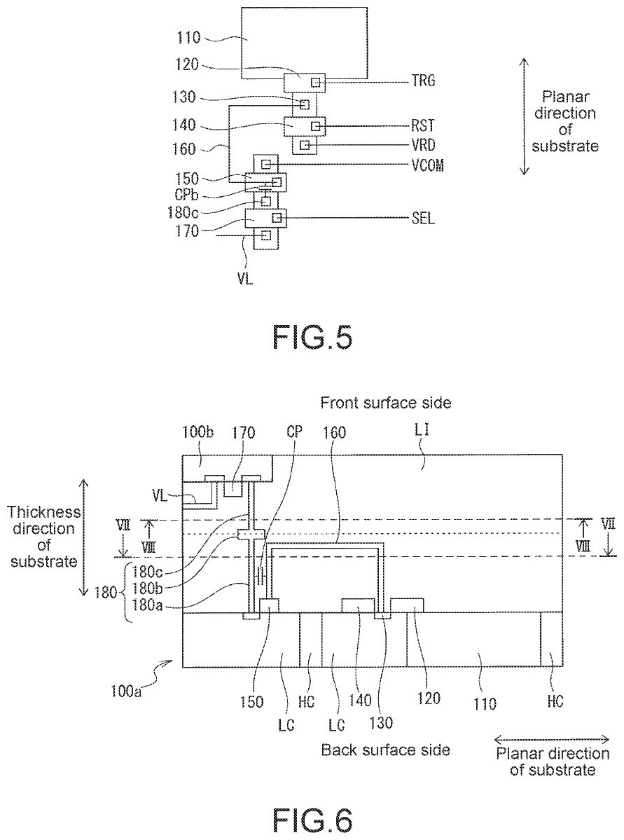

A solid-state image sensor according to a third embodiment is different from the first embodiment in that the second wiring 180 is formed between the amplifier transistor 150 and the selection transistor 170 as shown in FIG. 4 and FIG. 5. In the following description, description of the same portions as those in the first embodiment will be omitted.

The second wiring 180 is formed by, for example, providing a via between the amplifier transistor 150 and the selection transistor 170.

Further, the second wiring 180 according to the third embodiment includes a second wiring upstream portion 180a, a second wiring middle portion 180b, and a second wiring downstream portion 180c.

The second wiring upstream portion 180a forms the upstream side of the second wiring 180 on the semiconductor substrate 100. Further, the second wiring upstream portion 180a is formed in a straight line along the thickness direction of the semiconductor substrate 100 (up-and-down direction in FIG. 4).

One end of the second wiring upstream portion 180a is connected to the source electrode of the selection transistor 170. The other end of the second wiring upstream portion 180a is connected to one end of the second wiring middle portion 180b.

Further, a part of the second wiring upstream portion 180a faces a part of the first wiring 160 in the planar direction of the semiconductor substrate 100 (right-and-left direction in FIG. 4).

As a result, a first additional capacitance CPa is formed in portions where the first wiring 160 and the second wiring upstream portion 180a face each other. The magnitude of the first additional capacitance CPa has a value according to the distance between the first wiring 160 and the second wiring upstream portion 180a, the facing area of the portions where the first wiring 160 and the second wiring upstream portion 180a face each other, and the like.

The second wiring middle portion 180b is formed between the second wiring upstream portion 180a and the second wiring downstream portion 180c. Further, the second wiring middle portion 180b is formed in a straight line extending along the planar direction of the semiconductor substrate 100.

The second wiring downstream portion 180c forms the downstream side of the second wiring 180 on the semiconductor substrate 100. Further, the second wiring downstream portion 180c is formed in a straight line along the thickness direction of the semiconductor substrate 100.

One end of the second wiring downstream portion 180c is connected to the other end of the second wiring middle portion 180b.

Further, a part of the second wiring downstream portion 180c faces a part of the first wiring 160 in the planar direction of the semiconductor substrate 100. That is, at least a part of the first wiring 160, and at least a part of the second wiring upstream portion 180a and at least a part of the second wiring downstream portion 180c face each other along the planar direction of the semiconductor substrate 100.

As a result, a second additional capacitance CPb is formed in portions where the first wiring 160 and the second wiring downstream portion 180c face each other. The magnitude of the second additional capacitance CPb has a value according to the distance between the first wiring 160 and the second wiring downstream portion 180c, the facing area of the portions where the first wiring 160 and the second wiring downstream portion 180c face each other, and the like.

Further, the interval between the second wiring downstream portion 180c and the first wiring 160 is smaller than the interval between the second wiring upstream portion 180a and the first wiring 160. That is, the interval between at least a part of the first wiring 160 and at least a part of the second wiring upstream portion 180a facing each other and the interval between at least a part of the first wiring 160 and at least a part of the second wiring downstream portion 180c facing each other differ.

With the configuration of the third embodiment, by making a part of the second wiring 180 (the second wiring upstream portion 180a and the second wiring downstream portion 180c) face the first wiring 160, the conversion efficiency can be adjusted while dispersing the main variation factor of the feedback capacitance, similarly to the first embodiment. Therefore, it is possible to provide a solid-state image sensor capable of reducing the variation in conversion efficiency. This is because, in the solid-state image sensor in which the amplifier transistor 150 is connected to be source-grounded as in the present technology, the capacitance formed between the amplifier transistor 150 and the selection transistor 170 is also included as the feedback capacitance.

Further, by configuring the second wiring 180 to include the second wiring upstream portion 180a, the second wiring middle portion 180b, and the second wiring downstream portion 180c, the flexibility with respect to the configuration of the second wiring 180 can be improved.

Further, the interval between at least a part of the first wiring 160 and at least a part of the second wiring upstream portion 180a facing each other and the interval between at least a part of the first wiring 160 and at least a part of the second wiring downstream portion 180c facing each other differ. Therefore, the feedback capacitance can be adjusted by adjusting the respective intervals.

Note that the second wiring 180 includes the second wiring upstream portion 180a, the second wiring middle portion 180b, and the second wiring downstream portion 180c as the configuration of the second wiring 180 in the third embodiment, but the present technology is not limited thereto. That is, for example, the second wiring 180 may be formed to include only a portion that has one end connected to the source electrode of the selection transistor 170 and is formed in a straight line along the thickness direction of the semiconductor substrate 100.

### Fourth Embodiment

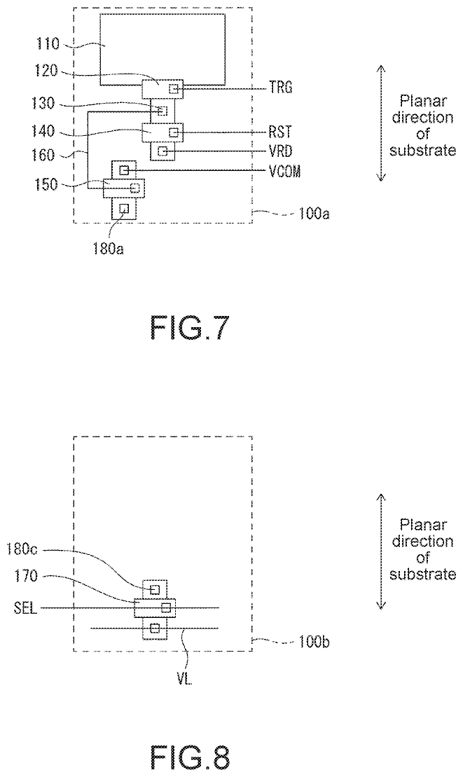

A solid-state image sensor according to a fourth embodiment includes two stacked semiconductor substrates (a first semiconductor substrate 100a and a second semiconductor substrate 100b) (two-layer structure), as shown in FIG. 6 to FIG. 8. Further, in the solid-state image sensor according to the fourth embodiment, the second wiring 180 includes the second wiring upstream portion 180a, the second wiring middle portion 180b, and the second wiring downstream portion 180c. Note that in the drawings, the insulating layer LI of the first semiconductor substrate 100a and the insulating layer LI of the second semiconductor substrate 100b are denoted by one reference symbol “LI”. The same applies to the following drawings.

The photodiode 110, the transfer transistor 120, the floating diffusion 130, and the reset transistor 140 are formed on the first semiconductor substrate 100a. Further, the amplifier transistor 150, the first wiring 160, the second wiring upstream portion 180a, and a part of the second wiring middle portion 180b are formed on the first semiconductor substrate 100a.

A part of the second wiring middle portion 180b, the second wiring downstream portion 180c, the selection transistor 170, and the vertical signal line VL are formed on the second semiconductor substrate 100b.

That is, the photodiode 110, the floating diffusion 130, and the amplifier transistor 150 are formed on one semiconductor substrate (the first semiconductor substrate 100a) of the plurality of semiconductor substrates. In addition thereto, the first wiring 160 and a part of the second wiring 180 (the second wiring upstream portion 180a and a part of the second wiring middle portion 180b) are formed on the first semiconductor substrate 100a.

Further, other parts of the second wiring 180 (a part of the second wiring middle portion 180b and the second wiring downstream portion 180c) are formed on a different semiconductor substrate (the second semiconductor substrate 100b) of the plurality of semiconductor substrates.

The second wiring upstream portion 180a is formed on the one semiconductor substrate 100 (the first semiconductor substrate 100a). Further, the second wiring upstream portion 180a is formed in a straight line along the thickness direction of the semiconductor substrate 100 (up-and-down direction in FIG. 6).

One end of the second wiring upstream portion 180a is connected to a drain electrode of the amplifier transistor 150.

Further, the second wiring upstream portion 180a faces a part of the first wiring 160 in the planar direction of the semiconductor substrate 100 (right-and-left direction in FIG. 6).

As a result, the additional capacitance CP is formed in portions where the first wiring 160 and the second wiring upstream portion 180a face each other. The magnitude of the additional capacitance CP has a value according to the distance between the first wiring 160 and the second wiring upstream portion 180a, the facing area of the portions where the first wiring 160 and the second wiring upstream portion 180a face each other, and the like.

The second wiring middle portion 180b is formed between the second wiring upstream portion 180a and the second wiring downstream portion 180c. Further, the second wiring middle portion 180b is formed in a straight line extending along the planar direction of the semiconductor substrate 100.

A part of the second wiring middle portion 180b is formed on a surface of the first semiconductor substrate 100a facing the second semiconductor substrate 100b. Further, the other end of the second wiring upstream portion 180a is connected to a part of the second wiring middle portion 180b.

The other part of the second wiring middle portion 180b is formed on the surface of the second semiconductor substrate 100b facing the first semiconductor substrate 100a. Further, one end of the second wiring downstream portion 180c is connected to the other part of the second wiring middle portion 180b.

The second wiring downstream portion 180c is formed on the different semiconductor substrate 100 (the second semiconductor substrate 100b). Further, the second wiring downstream portion 180c is formed in a straight line along the thickness direction of the semiconductor substrate 100 (up-and-down direction in FIG. 6).

The other end of the second wiring downstream portion 180c is connected to the source electrode of the selection transistor 170.

With the configuration of the fourth embodiment, the number of components disposed on each of the first semiconductor substrate 100a and the second semiconductor substrate 100b can be reduced as compared with a configuration in which all components are formed on one semiconductor substrate. Therefore, the flexibility of layout can be improved as compared with the configuration in which all components are formed on one semiconductor substrate.

### Modified Example of Fourth Embodiment

The second wiring 180 includes the second wiring upstream portion 180a, the second wiring middle portion 180b, and the second wiring downstream portion 180c as the configuration of the second wiring 180 in the fourth embodiment, but the present technology is not limited thereto. That is, for example, the second wiring 180 may include the second wiring upstream portion 180a and the second wiring downstream portion 180c.

Further, the solid-state image sensor includes two stacked semiconductor substrates 100 (the first semiconductor substrate 100a and the second semiconductor substrate 100b) in the fourth embodiment, but the present technology is not limited thereto. That is, for example, a configuration in which a solid-state image sensor includes three or more stacked semiconductor substrates by stacking a support substrate on the surface of the first semiconductor substrate 100a opposite to the surface facing the second semiconductor substrate 100b may be employed.

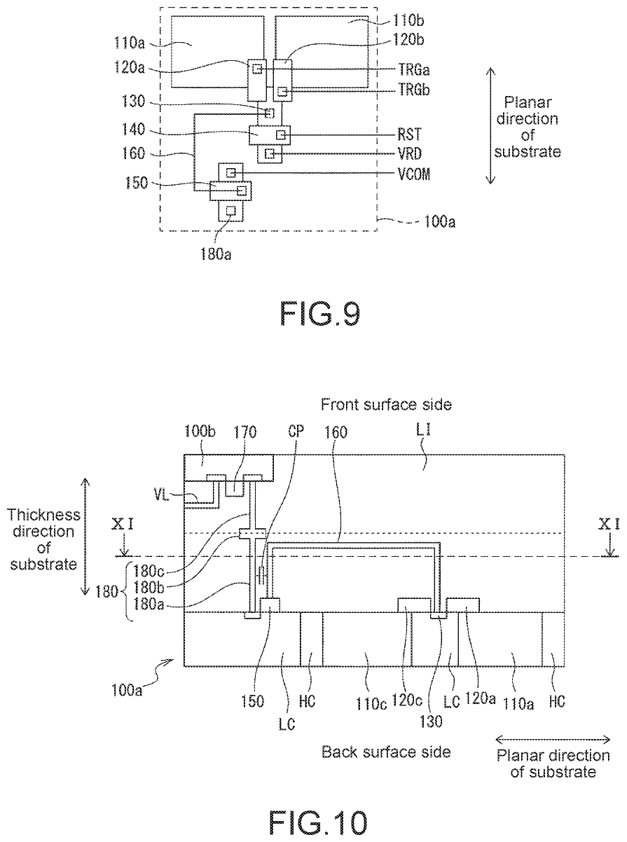

Further, for example, the signal charges accumulated in each of the two photodiodes 110a and 110b may be individually transferred to one floating diffusion 130, as shown in FIG. 9.

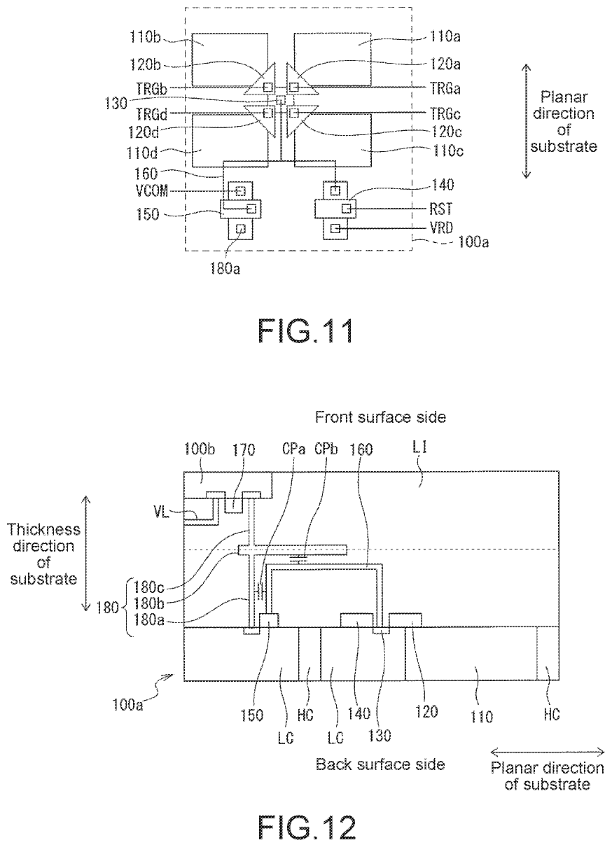

Further, for example, the signal charges accumulated in each of four photodiodes 110a to 110d may be individually transferred to one floating diffusion 130, as shown in FIG. 10 and FIG. 11.

### Fifth Embodiment

As shown in FIG. 12, a solid-state image sensor according to a fifth embodiment includes two stacked semiconductor substrates (the first semiconductor substrate 100a and the second semiconductor substrate 100b). Further, the second wiring 180 includes the second wiring upstream portion 180a, the second wiring middle portion 180b, and the second wiring downstream portion 180c.

The photodiode 110, the transfer transistor 120, the floating diffusion 130, and the reset transistor 140 are formed on the first semiconductor substrate 100a. Further, the amplifier transistor 150, the first wiring 160, the second wiring upstream portion 180a, and a part of the second wiring middle portion 180b are formed on the first semiconductor substrate 100a.

A part of the second wiring middle portion 180b, the second wiring downstream portion 180c, the selection transistor 170, and the vertical signal line VL are formed on the second semiconductor substrate 100b.

The second wiring upstream portion 180a is formed on the first semiconductor substrate 100a in a straight line along the thickness direction of the first semiconductor substrate 100a (up-and-down direction in FIG. 12).

One end of the second wiring upstream portion 180a is connected to the drain electrode of the amplifier transistor 150.

Further, a part of the second wiring upstream portion 180a faces a part of the first wiring 160 in the planar direction of the first semiconductor substrate 100a (right-and-left direction in FIG. 12).

As a result, the first additional capacitance CPa is formed in portions where the first wiring 160 and the second wiring upstream portion 180a face each other. The magnitude of the first additional capacitance CPa has a value according to the distance between the first wiring 160 and the second wiring upstream portion 180a, the facing area of the portions where the first wiring 160 and the second wiring upstream portion 180a face each other, and the like.

The second wiring middle portion 180b is formed between the second wiring upstream portion 180a and the second wiring downstream portion 180c. Further, the second wiring middle portion 180b is formed in a straight line extending along the planar direction of the two stacked semiconductor substrates (the first semiconductor substrate 100a and the second semiconductor substrate 100b).

A part of the second wiring middle portion 180b is formed on a surface of the first semiconductor substrate 100a facing the second semiconductor substrate 100b. Further, the other end of the second wiring upstream portion 180a is connected to a part of the second wiring middle portion 180b.

The other part of the second wiring middle portion 180b is formed on the surface of the second semiconductor substrate 100b facing the first semiconductor substrate 100a. Further, the one end of the second wiring downstream portion 180c is connected to the other part of the second wiring middle portion 180b.

The length of the second wiring middle portion 180b is set to such a length that a portion facing the first wiring 160 along the direction in which the plurality of semiconductor substrates (the first semiconductor substrate 100a and the second semiconductor substrate 100b) is stacked is formed in the second wiring middle portion 180b. That is, at least a part of the first wiring 160 and at least a part of the second wiring middle portion 180b face each other along a direction in which the plurality of semiconductor substrates is stacked.

Thus, the second additional capacitance CPb is formed in portions where a part of the first wiring 160 and a part of the second wiring middle portion 180b face each other. The magnitude of the second additional capacitance CPb has a value according to the distance between the first wiring 160 and the second wiring middle portion 180b, the facing area of the portions where the first wiring 160 and the second wiring middle portion 180b face each other, and the like.

The second wiring downstream portion 180c is formed on the second semiconductor substrate 100b. Further, the second wiring downstream portion 180c is formed in a straight line along the thickness direction of the second semiconductor substrate 100b.

The other end of the second wiring downstream portion 180c is connected to the source electrode of the selection transistor 170.

With the configuration of the fifth embodiment, the feedback capacitance can be increased as compared with the configuration in which an additional capacitance is formed only in the portions where the first wiring 160 and the second wiring upstream portion 180a face each other.

### Modified Example of Fifth Embodiment

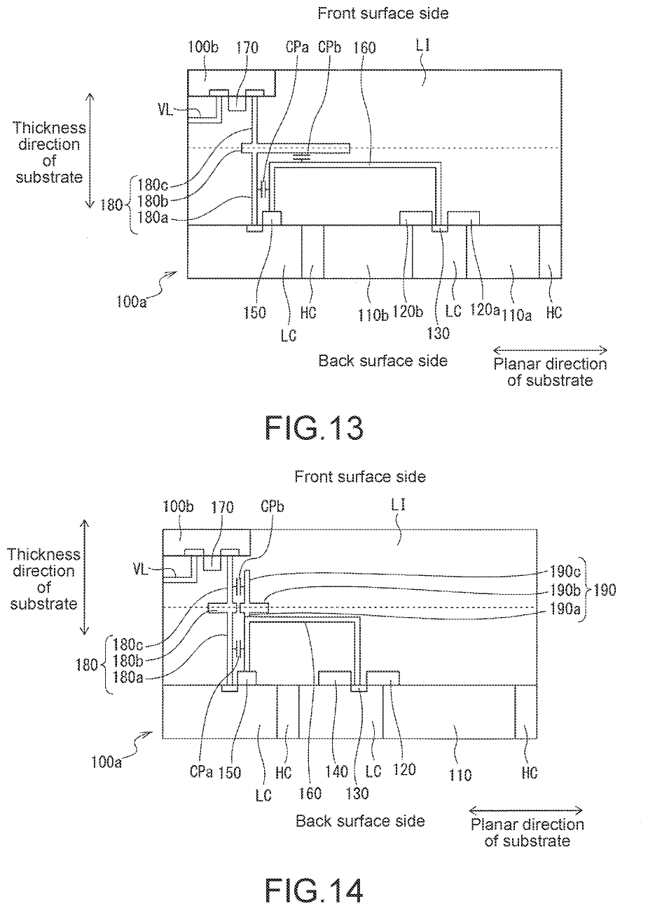

Only one photodiode 110 is connected to one floating diffusion 130 in the fifth embodiment, but the present technology is not limited this configuration. That is, for example, the signal charges accumulated in each of the two photodiodes 110a and 110b may be individually transferred to one floating diffusion 130 as shown in FIG. 13.

### Sixth Embodiment

As shown in FIG. 14, a solid-state image sensor according to a sixth embodiment includes two stacked semiconductor substrates 100 (the first semiconductor substrate 100a and the second semiconductor substrate 100b). Further, in the solid-state image sensor according to the sixth embodiment, the second wiring 180 includes the second wiring upstream portion 180a, the second wiring middle portion 180b, and the second wiring downstream portion 180c. Further, the solid-state image sensor according to the sixth embodiment includes a third wiring 190 that includes a third wiring upstream portion 190a, a third wiring middle portion 190b, and a third wiring downstream portion 190c and is connected to the first wiring 160 to be branched from the first wiring 160.

The photodiode 110, the transfer transistor 120, the floating diffusion 130, and the reset transistor 140 are formed on the first semiconductor substrate 100a. Further, the amplifier transistor 150, the first wiring 160, the second wiring upstream portion 180a, a part of the second wiring middle portion 180b, the third wiring upstream portion 190a, and a part of the third wiring middle portion 190b are formed on the first semiconductor substrate 100a.

A part of the second wiring middle portion 180b, the second wiring downstream portion 180c, a part of the third wiring middle portion 190b, the third wiring downstream portion 190c, the selection transistor 170, and the vertical signal line VL are formed on the second semiconductor substrate 100b.

The second wiring upstream portion 180a is formed in a straight line along the thickness direction of the first semiconductor substrate 100a (up-and-down direction in FIG. 14).

One end of the second wiring upstream portion 180a is connected to the drain electrode of the amplifier transistor 150.

Further, a part of the second wiring upstream portion 180a faces a part of the first wiring 160 in the planar direction of the first semiconductor substrate 100a (right-and-left direction in FIG. 14).

Thus, the first additional capacitance CPa is formed in portions where a part of the first wiring 160 and a part of the second wiring upstream portion 180a face each other. The magnitude of the first additional capacitance CPa has a value according to the distance between the first wiring 160 and the second wiring upstream portion 180a, the facing area of the portions where the first wiring 160 and the second wiring upstream portion 180a face each other, and the like.

The second wiring middle portion 180b is formed between the second wiring upstream portion 180a and the second wiring downstream portion 180c. Further, the second wiring middle portion 180b is formed in a straight line extending along the planar direction of the first semiconductor substrate 100a.

A part of the second wiring middle portion 180b is formed on a surface of the first semiconductor substrate 100a facing the second semiconductor substrate 100b. Further, the other end of the second wiring upstream portion 180a is connected to a part of the second wiring middle portion 180b.

The other part of the second wiring middle portion 180b is formed on the surface of the second semiconductor substrate 100b facing the first semiconductor substrate 100a. Further, the one end of the second wiring downstream portion 180c is connected to the other part of the second wiring middle portion 180b.

The second wiring downstream portion 180c is formed in a straight line along the thickness direction of the second semiconductor substrate 100b.

The other end of the second wiring downstream portion 180c is connected to the source electrode of the selection transistor 170.

The third wiring upstream portion 190a is formed on the first semiconductor substrate 100a in a straight line along the thickness direction of the first semiconductor substrate 100a.

One end of the third wiring upstream portion 190a is connected to a straight-line portion of the first wiring 160 along the thickness direction of the first semiconductor substrate 100a, which is connected to the gate electrode of the amplifier transistor 150.

The third wiring middle portion 190b is formed between the third wiring upstream portion 190a and the third wiring downstream portion 190c. Further, the third wiring middle portion 190b is formed in a straight line extending along the planar direction of the two stacked semiconductor substrates (the first semiconductor substrate 100a and the second semiconductor substrate 100b).

A part of the third wiring middle portion 190b is formed on the surface of the first semiconductor substrate 100a facing the second semiconductor substrate 100b. Further, the other end of the third wiring upstream portion 190a is connected to a part of the third wiring middle portion 190b.

The other part of the third wiring middle portion 190b is provided on the surface of the second semiconductor substrate 100b facing the first semiconductor substrate 100a. Further, one end of the third wiring downstream portion 190c is connected to the other part of the third wiring middle portion 190b.

The third wiring downstream portion 190c is formed in a straight line along the thickness direction of the second semiconductor substrate 100b.

Further, the third wiring downstream portion 190c faces a part of the second wiring downstream portion 180c in the planar direction (right-and-left direction in FIG. 14) of the semiconductor substrate (the second semiconductor substrate 100b). That is, at least a part of the second wiring 180 and at least a part of the third wiring 190 face each other.

As a result, the second additional capacitance CPb is formed in portions where the third wiring downstream portion 190c and the second wiring downstream portion 180c face each other. The magnitude of the second additional capacitance CPb has a value according to the distance between the third wiring downstream portion 190c and the second wiring downstream portion 180c, the facing area of the portions where the third wiring downstream portion 190c and the second wiring downstream portion 180c face each other, and the like.

Further, at least the portions where the second wiring 180 and the third wiring 190 face each other extend in parallel along the thickness direction of the semiconductor substrate (the second semiconductor substrate 100b).

With the configuration of the sixth embodiment, the feedback capacitance can be increased as compared with the configuration in which an additional capacitance is formed only in the portions where the first wiring 160 and the second wiring upstream portion 180a face each other.

### Modified Example of Sixth Embodiment

The second wiring 180 includes the second wiring upstream portion 180a, the second wiring middle portion 180b, and the second wiring downstream portion 180c as the configuration of the second wiring 180 in the sixth embodiment, but the present technology is not limited thereto. That is, for example, the second wiring 180 may include the second wiring upstream portion 180a and the second wiring downstream portion 180c. Similarly, the third wiring 190 may include the third wiring upstream portion 190a and the third wiring downstream portion 190c.

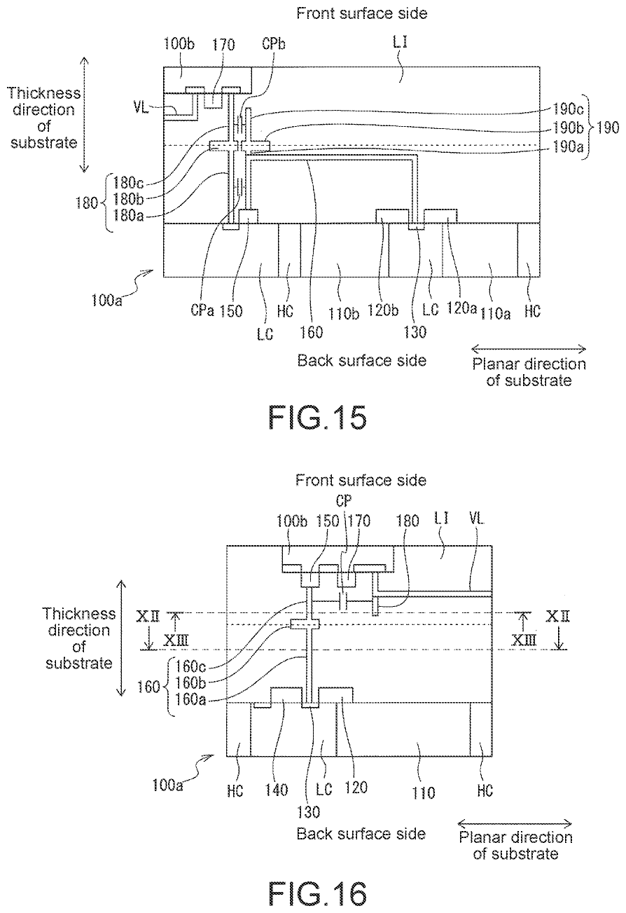

Further, for example, the signal charges accumulated in each of the two the photodiodes 110a and 110b may be individually transferred to one floating diffusion 130 as shown in FIG. 15.

### Seventh Embodiment

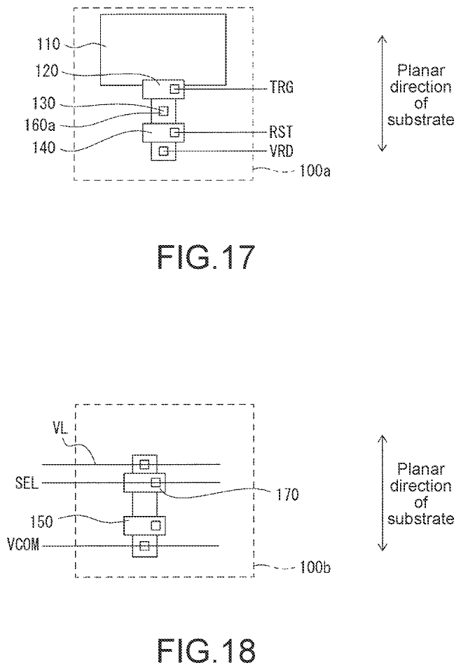

As shown in FIG. 16 to FIG. 18, a solid-state image sensor according to a seventh embodiment includes two stacked semiconductor substrates 100 (the first semiconductor substrate 100a and the second semiconductor substrate 100b). Further, in the solid-state image sensor according to the seventh embodiment, the first wiring 160 includes a first wiring upstream portion 160a, a first wiring middle portion 160b, and a first wiring downstream portion 160c.

The photodiode 110, the transfer transistor 120, the floating diffusion 130, the reset transistor 140, the first wiring upstream portion 160a, and a part of the first wiring middle portion 160b are formed on the first semiconductor substrate 100a.

The amplifier transistor 150, a part of the first wiring middle portion 160b, the first wiring downstream portion 160c, the selection transistor 170, the vertical signal line VL, and the second wiring 180 are formed on the second semiconductor substrate 100b.

Therefore, the photodiode 110, the floating diffusion 130, and the first wiring upstream portion 160a are formed on the one semiconductor substrate (the first semiconductor substrate 100a). Further, the amplifier transistor 150, the first wiring downstream portion 160c, the vertical signal line VL, and the second wiring 180 are formed on the different semiconductor substrate (the second semiconductor substrate 100b).

Further, the first wiring 160 includes the first wiring upstream portion 160a formed on the one semiconductor substrate (the first semiconductor substrate 100a), and the first wiring downstream portion 160c formed on the different semiconductor substrate (the second semiconductor substrate 100b). Further, the first wiring 160 includes the first wiring middle portion 160b formed between the first wiring upstream portion 160a and the first wiring downstream portion 160c.

The first wiring upstream portion 160a forms the upstream side of the first wiring 160 on the first semiconductor substrate 100a, and is formed in a straight line along the thickness direction of the first semiconductor substrate 100a (up-and-down direction in FIG. 16).

One end of the first wiring upstream portion 160a is connected to the gate electrode of the transfer transistor 120.

The first wiring middle portion 160b is formed in a straight line extending along the planar direction of the two stacked semiconductor substrates (the first semiconductor substrate 100a and the second semiconductor substrate 100b).

A part of the first wiring middle portion 160b is provided on the surface of the first semiconductor substrate 100a facing the second semiconductor substrate 100b. Further, the other end of the first wiring upstream portion 160a is connected to a part of the first wiring middle portion 160b.

The other part of the first wiring middle portion 160b is provided on the surface of the second semiconductor substrate 100b facing the first semiconductor substrate 100a. Further, one end of the first wiring downstream portion 160c is connected to the other part of the first wiring middle portion 160b.

The first wiring downstream portion 160c forms the downstream side of the first wiring 160 on the second semiconductor substrate 100b and is formed in a straight line along the thickness direction of the second semiconductor substrate 100b.

The other end of the first wiring downstream portion 160c is connected to the gate electrode of the amplifier transistor 150.

Further, a part of the first wiring downstream portion 160c faces the second wiring 180, one end of which is connected in the middle of the vertical signal line VL, in the planar direction of the second semiconductor substrate 100b (right-and-left direction in FIG. 16). That is, at least a part of the first wiring downstream portion 160c and at least a part of the second wiring 180 face each other.

As a result, the additional capacitance CP is formed in portions where the first wiring downstream portion 160c and the second wiring 180 face each other. The magnitude of the additional capacitance CP has a value according to the distance between the first wiring downstream portion 160c and the second wiring 180, the facing area of the portions where the first wiring downstream portion 160c and the second wiring 180 face each other, and the like.

Further, at least the portions where the first wiring downstream portion 160c and the second wiring 180 face each other extend in parallel along the thickness direction of the different semiconductor substrate (the second semiconductor substrate 100b).

With the configuration of the seventh embodiment, the number of components disposed on the first semiconductor substrate 100a can be reduced as compared with the configuration in which components in previous stages (on the upstream side) of the amplifier transistor 150 are formed on the first semiconductor substrate 100a. Therefore, the flexibility of layout can be improved.

### Modified Example of Seventh Embodiment

The first wiring 160 includes the first wiring upstream portion 160a, the first wiring middle portion 160b, and the first wiring downstream portion 160c as the configuration of the first wiring 160 in the seventh embodiment, but the present technology is not limited thereto. That is, for example, the first wiring 160 may include the first wiring upstream portion 160a and the first wiring downstream portion 160c.

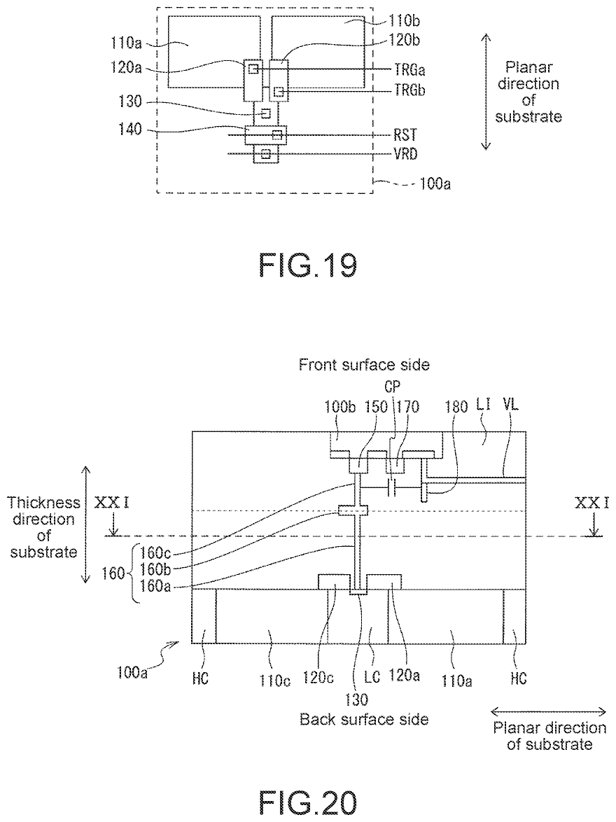

Further, for example, the signal charges accumulated in each of the two photodiodes 110a and 110b may be individually transferred to one floating diffusion 130 as shown in FIG. 19.

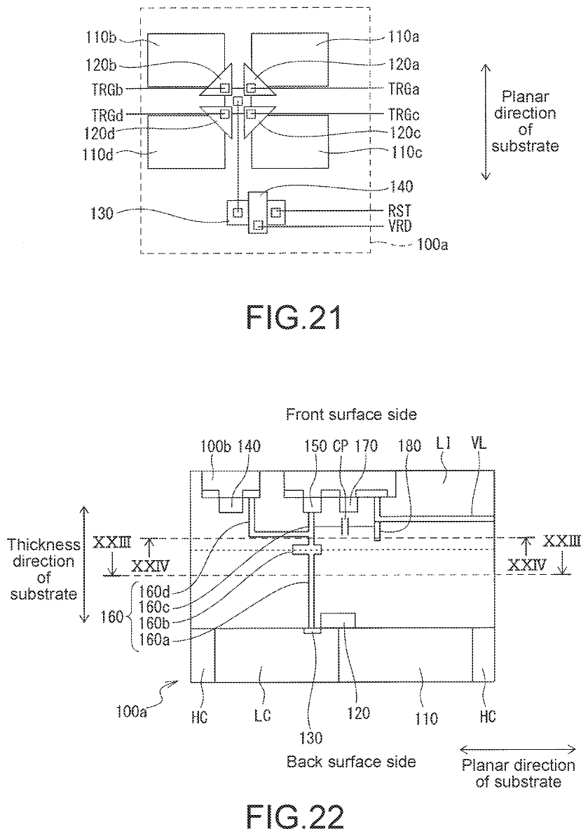

Further, for example, the signal charges accumulated in each of four photodiodes 110a to 110d may be individually transferred to one floating diffusion 130 as shown in FIG. 20 and FIG. 21.

### Eighth Embodiment

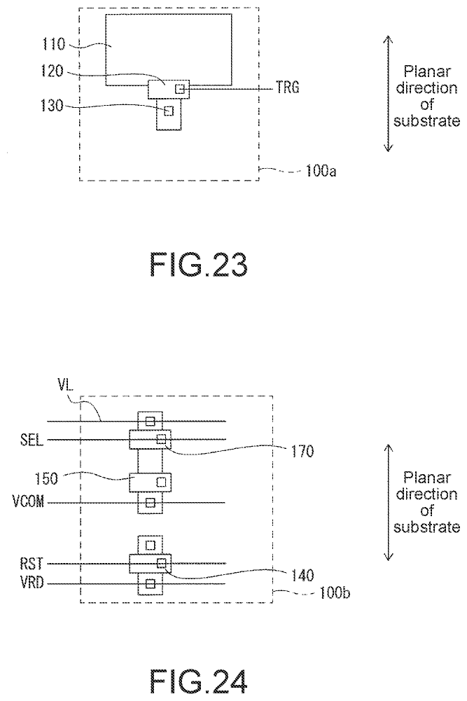

As shown in FIG. 22 to FIG. 24, a solid-state image sensor according to an eighth embodiment includes two stacked semiconductor substrates 100 (the first semiconductor substrate 100a and the second semiconductor substrate 100b). Further, in the solid-state image sensor according to the eighth embodiment, the first wiring 160 includes the first wiring upstream portion 160a, the first wiring middle portion 160b, the first wiring downstream portion 160c, and a first wiring branch portion 160d.

The photodiode 110, the transfer transistor 120, the floating diffusion 130, a part of the first wiring upstream portion 160a, and a part of the first wiring middle portion 160b are formed on the first semiconductor substrate 100a.

The reset transistor 140, the amplifier transistor 150, a part of the first wiring middle portion 160b, the first wiring downstream portion 160c, the first wiring branch portion 160d, the selection transistor 170, the vertical signal line VL, and the second wiring 180 are formed on the second semiconductor substrate 100b.

The first wiring upstream portion 160a forms the upstream side of the first wiring 160 on the first semiconductor substrate 100a, and is formed in a straight line along the thickness direction of the first semiconductor substrate 100a (up-and-down direction in FIG. 22).

One end of the first wiring upstream portion 160a is connected to the gate electrode of the transfer transistor 120.

The first wiring middle portion 160b is formed in a straight line extending along the planar direction of the two stacked semiconductor substrates (the first semiconductor substrate 100a and the second semiconductor substrate 100b).

A part of the first wiring middle portion 160b is provided on the surface of the first semiconductor substrate 100a facing the second semiconductor substrate 100b. Further, the other end of the first wiring upstream portion 160a is connected to a part of the first wiring middle portion 160b.

The other part of the first wiring middle portion 160b is provided on the surface of the second semiconductor substrate 100b facing the first semiconductor substrate 100a. Further, the one end of the first wiring downstream portion 160c is connected to the other part of the first wiring middle portion 160b.

The first wiring downstream portion 160c forms the downstream side of the first wiring 160 on the second semiconductor substrate 100b and is formed in a straight line along the thickness direction of the second semiconductor substrate 100b.

The other end of the first wiring downstream portion 160c is connected to the gate electrode of the amplifier transistor 150.

Further, a part of the first wiring downstream portion 160c faces the second wiring 180 in the planar direction of the semiconductor substrate 100 (right-and-left direction in FIG. 22).

As a result, the additional capacitance CP is formed in portions where the first wiring downstream portion 160c and the second wiring 180 face each other. The magnitude of the additional capacitance CP has a value according to the distance between the first wiring downstream portion 160c and the second wiring 180, the facing area of the portions where the first wiring downstream portion 160c and the second wiring 180 face each other, and the like.

The first wiring branch portion 160d is formed by branching from between both ends of the first wiring downstream portion 160c.

One end of the first wiring branch portion 160d is connected to the first wiring upstream portion 160a. The other end of the first wiring branch portion 160d is connected to the source electrode of the reset transistor 140.

With the configuration of the eighth embodiment, the number of components disposed on the first semiconductor substrate 100a can be reduced as compared with the configuration in which components in the previous stages (on the upstream side) of the reset transistor 140 are formed on the first semiconductor substrate 100a. Therefore, the flexibility of layout can be improved.

### Modified Example of Eighth Embodiment

The first wiring 160 includes the first wiring upstream portion 160a, the first wiring middle portion 160b, and the first wiring downstream portion 160c as the configuration of the first wiring 160 in the eighth embodiment, but the present technology is not limited thereto. That is, for example, the first wiring 160 may include the first wiring upstream portion 160a and the first wiring downstream portion 160c.

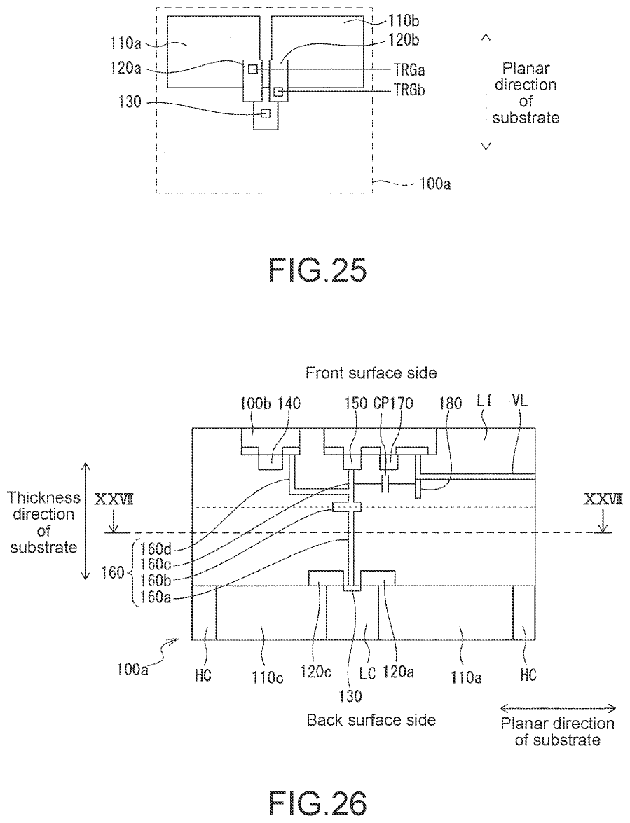

Further, for example, the signal charges accumulated in each of the two photodiodes 110a and 110b may be individually transferred to one floating diffusion 130 as shown in FIG. 25.

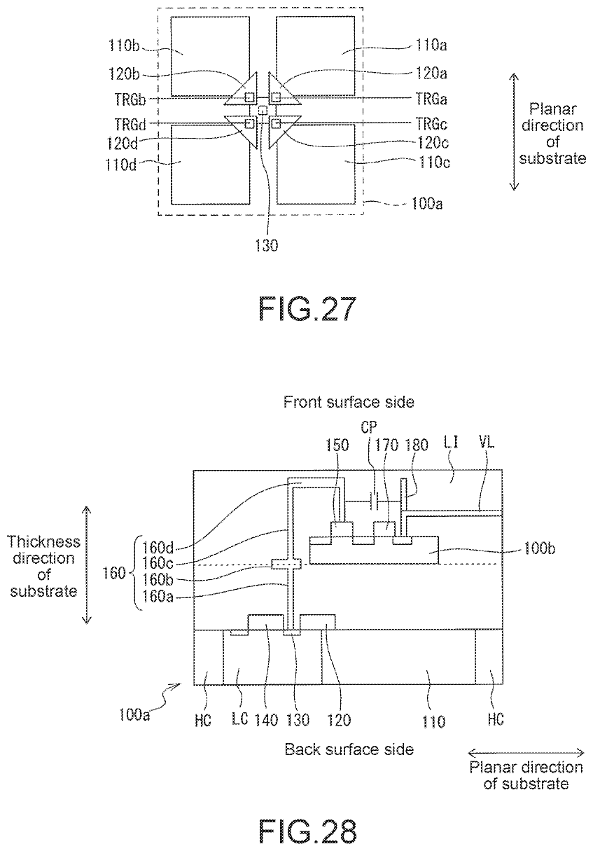

Further, for example, the signal charges accumulated in each of four photodiodes 110a to 110d may be individually transferred to one floating diffusion 130 as shown in FIG. 26 and FIG. 27.

### Ninth Embodiment

As shown in FIG. 28, a solid-state image sensor according to a ninth embodiment includes two stacked semiconductor substrates 100 (the first semiconductor substrate 100a and the second semiconductor substrate 100b). Further, in the solid-state image sensor according to the ninth embodiment, the first wiring 160 includes the first wiring upstream portion 160a, the first wiring middle portion 160b, the first wiring downstream portion 160c, and the first wiring branch portion 160d.

The photodiode 110, the transfer transistor 120, the floating diffusion 130, the reset transistor 140, a part of the first wiring upstream portion 160a, and a part of the first wiring middle portion 160b are formed on the first semiconductor substrate 100a.

The amplifier transistor 150, a part of the first wiring middle portion 160b, the first wiring downstream portion 160c, the first wiring branch portion 160d, the selection transistor 170, the vertical signal line VL, and the second wiring 180 are formed on the second semiconductor substrate 100b.

The first wiring upstream portion 160a forms the upstream side of the first wiring 160 on the first semiconductor substrate 100a, and is formed in a straight line along the thickness direction of the first semiconductor substrate 100a (up-and-down direction in FIG. 28).

One end of the first wiring upstream portion 160a is connected to the gate electrode of the transfer transistor 120.

The first wiring middle portion 160b is formed in a straight line extending along the planar direction of the two stacked semiconductor substrates (the first semiconductor substrate 100a and the second semiconductor substrate 100b).

A part of the first wiring middle portion 160b is provided on the surface of the first semiconductor substrate 100a facing the second semiconductor substrate 100b. Further, the other end of the first wiring upstream portion 160a is connected to a part of the first wiring middle portion 160b.

The other part of the first wiring middle portion 160b is provided on the surface of the second semiconductor substrate 100b facing the first semiconductor substrate 100a. Further, the one end of the first wiring downstream portion 160c is connected to the other part of the first wiring middle portion 160b.

The first wiring downstream portion 160c forms the downstream side of the first wiring 160 on the second semiconductor substrate 100b and is formed in a straight line along the thickness direction of the second semiconductor substrate 100b.

The other end of the first wiring downstream portion 160c is connected to one end of the first wiring branch portion 160d.

The other end of the first wiring branch portion 160d is connected to the gate electrode of the amplifier transistor 150.

Further, a part of the first wiring branch portion 160d faces the second wiring 180 in the planar direction of the semiconductor substrate 100 (right-and-left direction in FIG. 28).

As a result, the additional capacitance CP is formed in portions where the first wiring branch portion 160d and the second wiring 180 face each other. The magnitude of the additional capacitance CP has a value according to the distance between the first wiring branch portion 160d and the second wiring 180, the facing area of the portions where the first wiring branch portion 160d and the second wiring 180 face each other, and the like.

Further, in the solid-state image sensor according to the ninth embodiment, gate oxide films (not shown) of the amplifier transistor 150 and the selection transistor 170 are disposed at positions closer to the first semiconductor substrate 100a than the front surface of the second semiconductor substrate 100b as shown in FIG. 28.

With the configuration of the ninth embodiment, the flexibility in layout for disposing the components constituting the solid-state image sensor can be improved.

### First Application Example

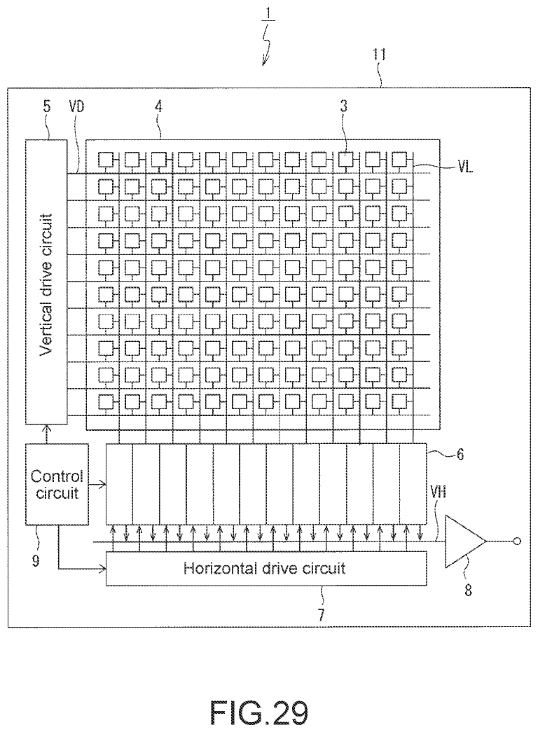

The solid-state image sensor according to the present technology may have the configuration shown in FIG. 29, for example.

A solid-state imaging device 1 shown in FIG. 29 is a CMOS image sensor. Further, the solid-state imaging device 1 has a pixel region 4 as an imaging area on the semiconductor substrate 100. Further, peripheral circuit units (5, 6, 7, 8, and 9) including, for example, a vertical drive circuit 5, a column selection circuit 6, a horizontal drive circuit 7, an output circuit 8, and a control circuit 9 are provided in the peripheral region of the pixel region 4.

The pixel region 4 has, for example, a plurality of unit pixels 3 (corresponding to the photodiode 110) two-dimensionally arranged in a matrix. In the unit pixel 3, for example, a pixel drive line VD (specifically, a row selection line and a reset control line) is wired for each pixel row, and the vertical signal line VL is wired for each pixel column. The pixel drive line VD transmits a drive signal for reading a signal from a pixel. One end of the pixel drive line VD is connected to the output end corresponding to the respective rows of the vertical drive circuit 5.

The vertical drive circuit 5 includes a shift register, an address decoder, and the like. The vertical drive circuit 5 drives the respective unit pixels 3 of the pixel region 4, for example, on a row-by-row basis. The signals output from the unit pixels 3 in the pixel row selectively scanned by the vertical drive circuit 5 are supplied to the column selection circuit 6 via the corresponding vertical signal line VL.

The column selection circuit 6 includes an amplifier, a horizontal selection switch, and the like provided for each vertical signal line VL.

The horizontal drive circuit 7 includes a shift register, an address decoder, and the like. The horizontal drive circuit 7 sequentially drives the horizontal selection switches of the column selection circuit 6 while scanning them. By the selective scanning by the horizontal drive circuit 7, the signals of the respective pixels transmitted via the respective vertical signal lines VL are sequentially output to a horizontal signal line VH and transmitted to the outside of the semiconductor substrate 100 via the horizontal signal line VH.

The circuit unit including the vertical drive circuit 5, the column selection circuit 6, the horizontal drive circuit 7, and the horizontal signal line VH may be formed on the semiconductor substrate 100 or may be disposed on an external control IC. Further, the circuit unit may be formed on another substrate connected by a cable or the like.

The control circuit 9 receives clocks supplied from the outside of the semiconductor substrate 100, data instructing operation modes, and the like, and outputs data such as internal information of the solid-state imaging device 1. Further, the control circuit 9 includes a timing generator for generating various timing signals, and performs drive control of peripheral circuits such as the vertical drive circuit 5, the column selection circuit 6, and the horizontal drive circuit 7 on the basis of various timing signals generated by the timing generator.

### Second Application Example

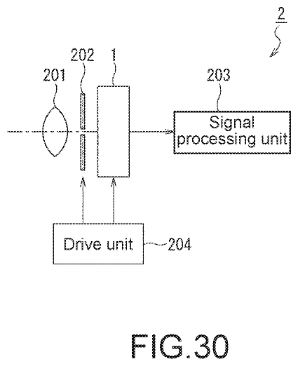

The solid-state image sensor according to the present technology can be applied to all types of electronic apparatuses having an imaging function, such as a camera system including a digital still camera, a video camera, and the like, and a mobile phone having an imaging function. For example, FIG. 30 shows a schematic configuration of an electronic apparatus 2 (camera) as a second application example.

The electronic apparatus 2 is, for example, a video camera capable of capturing a still image or a moving image, and includes the solid-state imaging device 1, an optical system (optical lens) 201, a shutter device 202, a drive unit 204 that drives the solid-state imaging device 1 and the shutter device 202, and a signal processing unit 203.

The optical system 201 guides image light (incident light) from a subject to the pixel region 4 of the solid-state imaging device 1. Note that the optical system 201 may include a plurality of optical lens.

The shutter device 202 controls a period during which the solid-state imaging device 1 is irradiated with light and a period during which light is shielded.

The drive unit 204 controls the transfer operation of the solid-state imaging device 1 and the shutter operation of the shutter device 202.

The signal processing unit 203 performs various types of signal processing on the signal output from the solid-state imaging device 1. The video signal on which signal processing has been performed is stored in a storage medium such as a memory, or is output to a monitor or the like.

### Other Embodiments

As described above, although the embodiments of the present technology have been described, the discussion and drawings that form a part of this disclosure are not to be understood as limiting the present technology. Various alternative embodiments, examples, and operational technologies will be apparent to those skilled in the art from this disclosure.

In addition, it is needless to say that the present technology includes various embodiments and the like that are not described herein, such as configurations in which the respective configurations described in the above-mentioned embodiments are arbitrarily applied. Accordingly, the technical scope of the present technology is determined only by matters used to specify the invention in the claims that are reasonable from the above description.

Further, in each of the above-mentioned embodiments, the configuration of the back surface irradiation solid-state imaging device has been exemplified, but the content of the present disclosure is also applicable to the front surface irradiation solid-state imaging device. Further, in the solid-state imaging device according to the present disclosure, all of components described in the above-mentioned embodiments and the like need not be provided, and conversely, other components may be provided. Further, the technology according to the present disclosure can be applied not only to a solid-state imaging device but also to, for example, a solar battery. Further, the technology according to the present disclosure can be applied not only to a monitoring camera or the like, but also to, for example, a mobile device such as a mobile phone or an in-vehicle device.

Note that the effects described herein are merely illustrative and not restrictive, and may have other effects.

It should be noted that the present technology may also take the following configurations.

(1) A solid-state image sensor, including:

a floating diffusion to which signal charges that have been accumulated in a photodiode that performs photoelectric conversion are transferred;

a common-source amplifier transistor that reads the signal charges that have been transferred to the floating diffusion as an electrical signal and amplifies the electrical signal;

a first wiring that connects the floating diffusion and the amplifier transistor to each other; and

a second wiring disposed on an electrically-downstream side of the amplifier transistor, in which at least a part of the first wiring and at least a part of the second wiring face each other.

(2) The solid-state image sensor according to (1) above, further including

a semiconductor substrate on which the floating diffusion and the amplifier transistor are formed, in which

at least portions where the first wiring and the second wiring face each other extend in parallel along a thickness direction of the semiconductor substrate.

(3) The solid-state image sensor according to (2) above, further including

a semiconductor substrate on which the floating diffusion and the amplifier transistor are formed, in which

the second wiring includes a second wiring upstream portion that forms an upstream side of the second wiring on the semiconductor substrate and a second wiring downstream portion that forms a downstream side of the second wiring on the semiconductor substrate,

the at least a part of the first wiring, and at least a part of the second wiring upstream portion and at least a part of the second wiring downstream portion face each other along a planar direction of the semiconductor substrate, and

an interval between the at least a part of the first wiring and the at least a part of the second wiring upstream portion facing each other and a distance between the at least a part of the first wiring and the at least a part of the second wiring downstream portion facing each other differ.

(4) The solid-state image sensor according to (1) above, further including

a plurality of stacked semiconductor substrates, in which

the photodiode, the floating diffusion, the amplifier transistor, the first wiring, and a second wiring upstream portion that forms an upstream side of the second wiring are formed on one semiconductor substrate of the plurality of semiconductor substrates, and

a second wiring downstream portion that forms a downstream side of the second wiring is formed on a different semiconductor substrate of the plurality of semiconductor substrates.

(5) The solid-state image sensor according to (4) above, in which

the at least a part of the first wiring and at least a part of the second wiring upstream portion face each other along a planar direction of the one semiconductor substrate.

(6) The solid-state image sensor according to (4) above, in which

the second wiring includes the second wiring upstream portion, the second wiring downstream portion, and a second wiring middle portion that is formed between the second wiring upstream portion and the second wiring downstream portion and extends along a planar direction of the stacked semiconductor substrates, and

the at least a part of the first wiring and at least a part of the second wiring middle portion face each other along a direction in which the plurality of semiconductor substrates is stacked.

(7) The solid-state image sensor according to (6) above, in which

the at least a part of the first wiring and at least a part of the second wiring upstream portion face each other along a planar direction of the one semiconductor substrate.

(8) The solid-state image sensor according to any one of (1) to (7) above, further including

a vertical signal line for outputting an electrical signal amplified by the amplifier transistor, in which

one end of the second wiring is connected in the middle of the vertical signal line or to a node of the vertical signal line.

(9) The solid-state image sensor according to (1) above, further including

a plurality of stacked semiconductor substrates; and

a vertical signal line for outputting an electrical signal amplified by the amplifier transistor, in which

the first wiring includes a first wiring upstream portion that forms an upstream side of the first wiring on one semiconductor substrate of the plurality of semiconductor substrates and a first wiring downstream portion that forms a downstream side of the first wiring on a different semiconductor substrate of the plurality of semiconductor substrates,

the photodiode and the floating diffusion are formed on the one semiconductor substrate,

the amplifier transistor, the second wiring, and the vertical signal line are formed on the different semiconductor substrate,

one end of the second wiring is connected in the middle of the vertical signal line, and

at least a part of the first wiring downstream portion and at least a part of the second wiring face each other.

(10) The solid-state image sensor according to (9) above, in which

at least portions where the first wiring downstream portion and the second wiring face each other extend in parallel along a thickness direction of the different semiconductor substrate.

(11) The solid-state image sensor according to any one of (1) to (10) above, further including

a plurality of the photodiodes, in which

signal charges accumulated in each of the plurality of photodiodes are individually transferred to the one floating diffusion.

(12) The solid-state image sensor according to any one of (1) to (11) above, further including

a third wiring branching from the first wiring, in which

the at least a part of the second wiring and at least a part of the third wiring face each other.

(13) The solid-state image sensor according to (12) above, further including

a semiconductor substrate on which the floating diffusion and the amplifier transistor are formed, in which

at least portions where the second wiring and the third wiring face each other extend in parallel along a thickness direction of the semiconductor substrate.

(14) The solid-state image sensor according to any one of (1) to (13) above, in which

a length of portions where the first wiring and the second wiring face each other is longer than an interval between the portions.

### REFERENCE SIGNS LIST

1 solid-state imaging device, 2 electronic apparatus, 3 unit pixel, 4 pixel region, 5 vertical drive circuit, 6 column selection circuit, 7 horizontal drive circuit, 8 output circuit, 9 control circuit, 100 semiconductor substrate, 100a first semiconductor substrate, 100b second semiconductor substrate, 110 photodiode, 120 transfer transistor, 130 floating diffusion, 140 reset transistor, 150 amplifier transistor, 160 first wiring, 160a first wiring upstream portion, 160b first wiring middle portion, 160c first wiring downstream portion, 160d first wiring branch portion, 170 selection transistor, 180 second wiring, 180a second wiring upstream portion, 180b second wiring middle portion, 180c second wiring downstream portion, 190 third wiring, 190a third wiring upstream portion, 190b third wiring middle portion, 190c third wiring downstream portion, CP additional capacitance, CPa first additional capacitance, CPb second additional capacitance, VL vertical signal line, VD pixel drive line, VH horizontal signal line, HC high-concentration region, LClow-concentration region, LI insulating layer, 201 optical system, 202 shutter device, 203 signal processing unit, 204 drive unit, OL facing portion length, WI wiring interval

1. A solid-state image sensor, comprising:
a floating diffusion to which signal charges that have been accumulated in a photodiode that performs photoelectric conversion are transferred;
a common-source amplifier transistor that reads the signal charges that have been transferred to the floating diffusion as an electrical signal and amplifies the electrical signal;
a first wiring that connects the floating diffusion and the amplifier transistor to each other; and
a second wiring disposed on an electrically-downstream side of the amplifier transistor, wherein
at least a part of the first wiring and at least a part of the second wiring face each other.

2. The solid-state image sensor according to claim 1, further comprising
a semiconductor substrate on which the floating diffusion and the amplifier transistor are formed, wherein
at least portions where the first wiring and the second wiring face each other extend in parallel along a thickness direction of the semiconductor substrate.

3. The solid-state image sensor according to claim 2, further comprising
a semiconductor substrate on which the floating diffusion and the amplifier transistor are formed, wherein
the second wiring includes a second wiring upstream portion that forms an upstream side of the second wiring on the semiconductor substrate and a second wiring downstream portion that forms a downstream side of the second wiring on the semiconductor substrate,
the at least a part of the first wiring, and at least a part of the second wiring upstream portion and at least a part of the second wiring downstream portion face each other along a planar direction of the semiconductor substrate, and
an interval between the at least a part of the first wiring and the at least a part of the second wiring upstream portion facing each other and a distance between the at least a part of the first wiring and the at least a part of the second wiring downstream portion facing each other differ.

4. The solid-state image sensor according to claim 1, further comprising
a plurality of the photodiodes, wherein
signal charges accumulated in each of the plurality of photodiodes are individually transferred to the one floating diffusion.

5. The solid-state image sensor according to claim 1, further comprising
a vertical signal line for outputting an electrical signal amplified by the amplifier transistor, wherein
one end of the second wiring is connected in the middle of the vertical signal line or to a node of the vertical signal line.

6. The solid-state image sensor according to claim 1, further comprising
a plurality of stacked semiconductor substrates, wherein
the photodiode, the floating diffusion, the amplifier transistor, the first wiring, and a second wiring upstream portion that forms an upstream side of the second wiring are formed on one semiconductor substrate of the plurality of semiconductor substrates, and
a second wiring downstream portion that forms a downstream side of the second wiring is formed on a different semiconductor substrate of the plurality of semiconductor substrates.

7. The solid-state image sensor according to claim 6, wherein
the at least a part of the first wiring and at least a part of the second wiring upstream portion face each other along a planar direction of the one semiconductor substrate.

8. The solid-state image sensor according to claim 6, wherein
the second wiring includes the second wiring upstream portion, the second wiring downstream portion, and a second wiring middle portion that is formed between the second wiring upstream portion and the second wiring downstream portion and extends along a planar direction of the stacked semiconductor substrates, and
the at least a part of the first wiring and at least a part of the second wiring middle portion face each other along a direction in which the plurality of semiconductor substrates is stacked.

9. The solid-state image sensor according to claim 8, wherein
the at least a part of the first wiring and at least a part of the second wiring upstream portion face each other along a planar direction of the one semiconductor substrate.

10. The solid-state image sensor according to claim 1, further comprising
a third wiring branching from the first wiring, wherein
the at least a part of the second wiring and at least a part of the third wiring face each other.

11. The solid-state image sensor according to claim 10, further comprising
a semiconductor substrate on which the floating diffusion and the amplifier transistor are formed, wherein
at least portions where the second wiring and the third wiring face each other extend in parallel along a thickness direction of the semiconductor substrate.

12. The solid-state image sensor according to claim 1, further comprising
a plurality of stacked semiconductor substrates; and
a vertical signal line for outputting an electrical signal amplified by the amplifier transistor, wherein
the first wiring includes a first wiring upstream portion that forms an upstream side of the first wiring on one semiconductor substrate of the plurality of semiconductor substrates and a first wiring downstream portion that forms a downstream side of the first wiring on a different semiconductor substrate of the plurality of semiconductor substrates,
the photodiode and the floating diffusion are formed on the one semiconductor substrate,
the amplifier transistor, the second wiring, and the vertical signal line are formed on the different semiconductor substrate,
one end of the second wiring is connected in the middle of the vertical signal line, and
at least a part of the first wiring downstream portion and at least a part of the second wiring face each other.

13. The solid-state image sensor according to claim 12, wherein
at least portions where the first wiring downstream portion and the second wiring face each other extend in parallel along a thickness direction of the different semiconductor substrate.

14. The solid-state image sensor according to claim 1, wherein
a length of portions where the first wiring and the second wiring face each other is longer than an interval between the portions.
